(19) United States
(12) Patent Application Publication
(10) Pub. No.: US 2005/0014382 A1
(43) Pub. Date: Jan. 20, 2005

(54) Etching apparatus and method

(75) Inventors: Jin-seok Lee, Seoul City (KR); Dong-cheol Kim, Anyang city (KR); Jae-bong Kim, Suwon city (JP); In-ho Choi, Seoul city (KR); Jung-wook Kim, Seongnam city (KR); Dong-seok Baek, Suwon city (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 10/811,896

(22) Filed: Mar. 30, 2004

(30) Foreign Application Priority Data
Jul. 16, 2003 (KR) 2003-48881

(51) Int. Cl. C23F 1/00; H01L 21/306; H01L 21/302; H01L 21/461

(52) U.S. Cl. 438/706

(57) ABSTRACT

An etching apparatus and method of etching, the etching apparatus comprises a gas injector injecting reaction gas into a chamber in which semiconductor wafer is accommodated. The gas injector comprises at least a pair of gas suppliers having a gas supplying hole and a gas distributor having a loop-typed upper partition wall protruding from a central zone of an upper side of a plate, and a loop-typed bottom partition wall protruding from a central zone of a bottom side of the plate. A showerhead is disposed having a gap with the gas distributor, and injecting the reaction gas into the chamber. The etching apparatus independently controls an amount of reaction gas injected into a central zone and an edge zone of a chamber when the reaction gas is injected into the chamber, thereby controlling uniformity of density of plasma, deposition speed, etching speed, and the like in the etching process.

### CROSS-REFERENCE TO RELATED APPLICATIONS

This application claims the benefit of Korean Patent Application No. 2003-48881, filed Jul. 16, 2003, in the Korean Intellectual Property Office, the disclosure of which is incorporated herein by reference.

### BACKGROUND OF THE INVENTION

1. Field of the Invention

The present invention relates to an etching apparatus, and more particularly, to an etching apparatus having an improved gas injector.

2. Description of the Related Art

In general, a dry-etching method and a wet-etching method are used to etch an oxidized layer generated in a semiconductor wafer during a semiconductor process.

The dry-etching method removes the oxidized layer of the semiconductor wafer using plasma generated between an upper and a bottom electrode having power applied thereto, while a semiconductor substrate is disposed in a vacuum chamber and a reaction gas is injected therein.

The wet-etching method removes the oxidized layer of the semiconductor wafer by soaking the wafer for a predetermined time in a container filled with an acid, and the acid removes the oxidized layer.

A conventional etching apparatus using the dry-etching method includes a gas distributor disposed in an upper part of a vacuum chamber, distributing the reaction gas and injecting it therein, and a gas distributor. An example of a conventional apparatus is described in U.S. Pat. No. 6,245,192. The conventional etching apparatus includes a showerhead exposed inside the vacuum chamber that is positioned over the semiconductor wafer in the vacuum chamber. A plurality of baffle plates are disposed in an upper part of the showerhead, and a supporting plate has supply holes disposed in an upper part of the plurality of baffle plates so as to supply the reaction gas.

The plurality of baffle plates include a bottom baffle plate disposed on an upper part of the showerhead, a middle baffle plate disposed above the bottom baffle plate, and an upper baffle plate, having a partition wall, disposed on an upper part of the middle baffle plate.

The partition wall circumscribes the upper baffle plate and divides a gap, formed between the upper baffle plate and the supporting plate, into a central zone and an edge zone. Thus, the flow of the reaction gas passing through the supply hole of the supporting plate is divided into the central zone and the middle zone, and is supplied to a gap between the supporting plate and the upper baffle plate.

The divided reaction gas is joined and mixed in the gap between the upper baffle plate and the middle baffle plate. The gas flows to a gap formed between the middle baffle plate and the bottom baffle plate and a gap between the bottom baffle plate and the showerhead sequentially. The gas is supplied to the vacuum chamber through a penetrating hole formed in the showerhead.

The reaction gas passing through a supply hole of the supporting plate is separated into the central zone and the edge zone when the reaction gas is supplied into a gap formed between the supporting plate and the upper baffle plate. The separated reaction gas is mixed when it moves to a gap formed between the upper baffle plate and the middle baffle plate, and then is supplied into the vacuum chamber. Thus, it is difficult to control the amount of reaction gas injected to the central zone and from the edge zone uniformly when the reaction gas is passing through the penetrating hole of the showerhead.

Therefore, an etching apparatus and method are desired that independently control the amount of the gas injected to the central zone and the edge zone of the showerhead so that density and speed of the gas in the wafer of the vacuum chamber can be controlled, and thereby enabling a control of the uniformity of density of plasma, deposition rate, etching speed, and the like in the dry-etching process.

### SUMMARY OF THE INVENTION

Accordingly, it is an aspect of the present invention to provide an etching apparatus independently controlling an amount of reaction gas injected into a central zone and an edge zone of a chamber when the reaction gas is injected into the chamber, and thereby controlling uniformity of density of plasma, deposition speed, etching speed, and the like, in the etching process.

According to an aspect of the present invention an etching apparatus is provided comprising a gas injector injecting reaction gas into a chamber in which a semiconductor wafer is accommodated. The gas injector includes at least a pair of gas suppliers having a gas supplying hole, and a gas distributor having a loop-typed upper partition wall protruding from a central zone of an upper side of a plate. A loop-typed bottom partition wall protrudes from a central zone of a bottom side of the plate, and a showerhead is disposed so as to have a gap with the gas distributor, and injecting the reaction gas into the chamber.

According to an aspect of the invention, the etching apparatus further comprises a first gap formed between the gas distributor and the gas supplier, and a second gap formed between the gas distributor and the showerhead.

According to an aspect of the invention, the upper partition wall divides the first gap into a first central zone and a first edge zone, whereas the bottom partition wall divides the second gap into a second central zone and a second edge zone.

According to an aspect of the invention, either one of the pair of gas suppliers connects to the first central zone, and the other one connects to the first edge zone.

According to an aspect of the invention, the first central zone has a plurality of first gas distribution holes connected with the second central zone passing through a planar side of the gas distributor, and the first edge zone has a plurality of second gas distribution holes connected with the second edge zone passing through the planar side of the gas distributor.

According to an aspect of the invention, the etching apparatus further comprises an MFC (Mass Flow Controller) independently controlling the amount of reaction gases respectively supplied into the first central zone and the first edge zone.

According to an aspect of the invention, the etching apparatus further comprises a control valve independently supplying the reaction gas into the first central zone and the first edge zone.

According to an aspect of the invention, the gas distributor contains aluminuim alloy, and the showerhead contains silicon.

Additional aspects and/or advantages of the invention will be set forth in part in the description which follows and, in part, will be obvious from the description, or may be learned by practice of the invention.

### BRIEF DESCRIPTION OF THE DRAWINGS

The above and/or other aspects and advantages of the present invention will become apparent and more readily appreciated from the following description of the embodiments, taken in conjunction with the accompany drawings of which:

FIG. 1 is a schematic view of an etching apparatus according to an aspect of the present invention;

FIG. 2 is a sectional perspective view of a gas injector of the etching apparatus shown in FIG. 1;

FIG. 3 is a frontal view of the etching apparatus shown in FIG. 2;

FIG. 4 is an enlarged view of FIG. 2;

FIG. 5 is a perspective view of the etching apparatus excluding a gas supplier shown in FIG. 3;

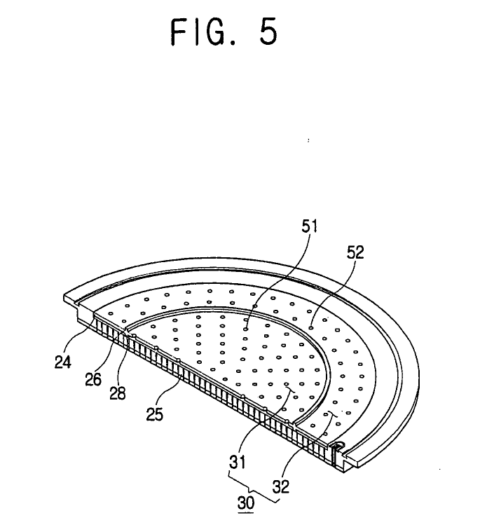

FIG. 6 is a frontal view of FIG. 4; and

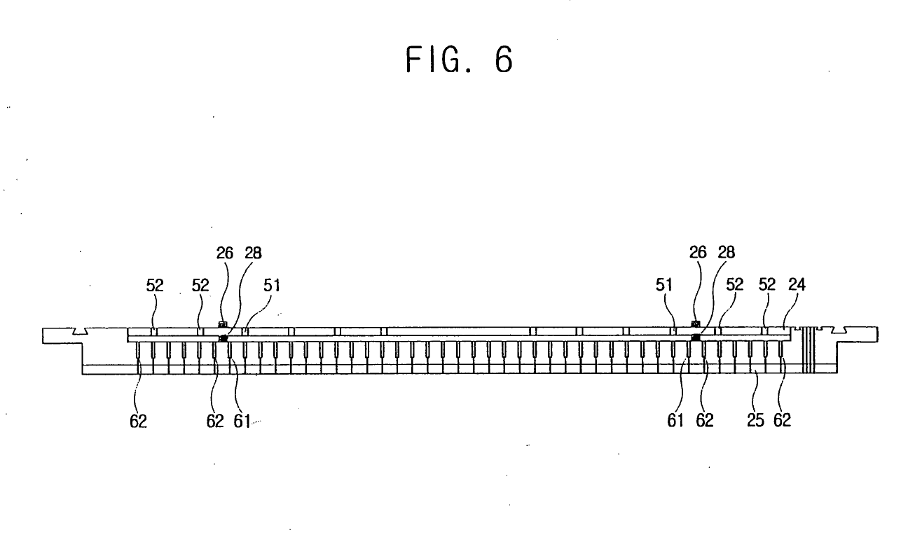

FIG. 7 is a sectional perspective view of a gas injector according to an another embodiment of the present invention.

### DETAILED DESCRIPTION OF THE PREFERRED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

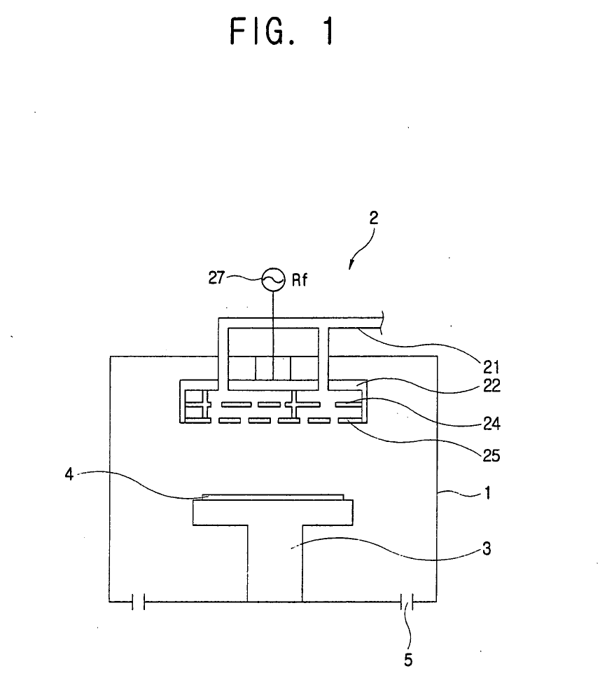

As illustrated in FIG. 1, an etching apparatus comprises a chamber 1, a gas injector 2 disposed in an inner upper part of the chamber 1, and a support 3 disposed in a bottom part of the chamber 1 so as to support a semiconductor wafer 4 to oppose the gas injector 2. A gas outlet 5 ejects a flue gas after a reaction process.

The chamber 1 is a sealed space to form a vacuum therein, and a space into which the reaction gas is supplied for etching the semiconductor wafer 4.

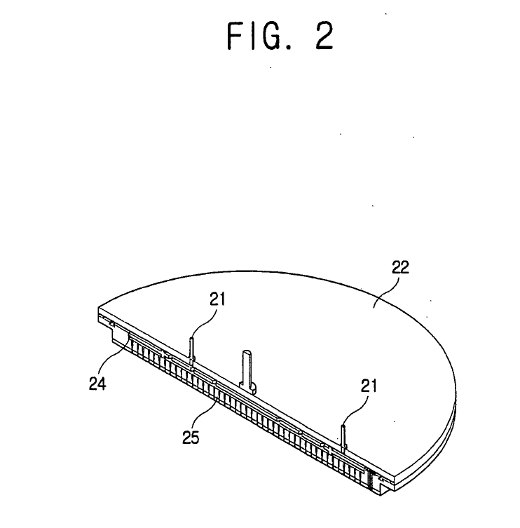

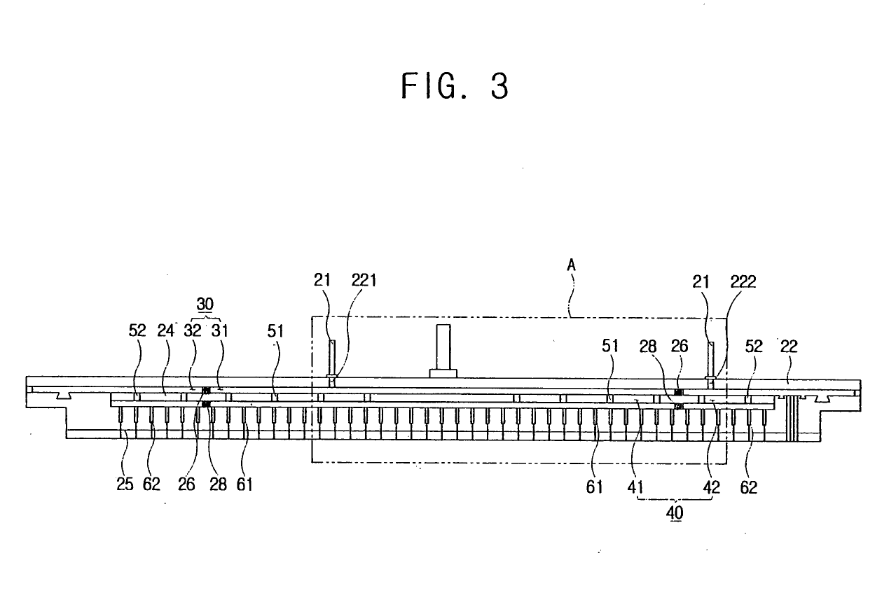

As shown in FIG. 2 and FIG. 3, the gas injector 2, disposed in an upper part of the chamber 1, comprises a supply pipe 21 supplying the reaction gas, and a gas supplier 22 including a first gas supply hole 221 and a second gas supply hole 222. A gas distributor 24 opposes the gas supplier 22 forming a gap therebetween. A showerhead 25 opposes the gas distributor 24, having a gap therebetween injecting the reaction gas into the chamber 1. After being sequentially layered, a first gap 30 is formed between the gas supplier 22 and the gas distributor 24 and a second gap 40 is formed between the gas distributor 24 and the showerhead 25.

Rf power 27 is applied from outside of the chamber 1 to form an electrode to form plasma inside the chamber. RF power is applied to the gas supplier 22 and the gas distributor 24 is used as an upper electrode. The support 3 is used as a bottom electrode.

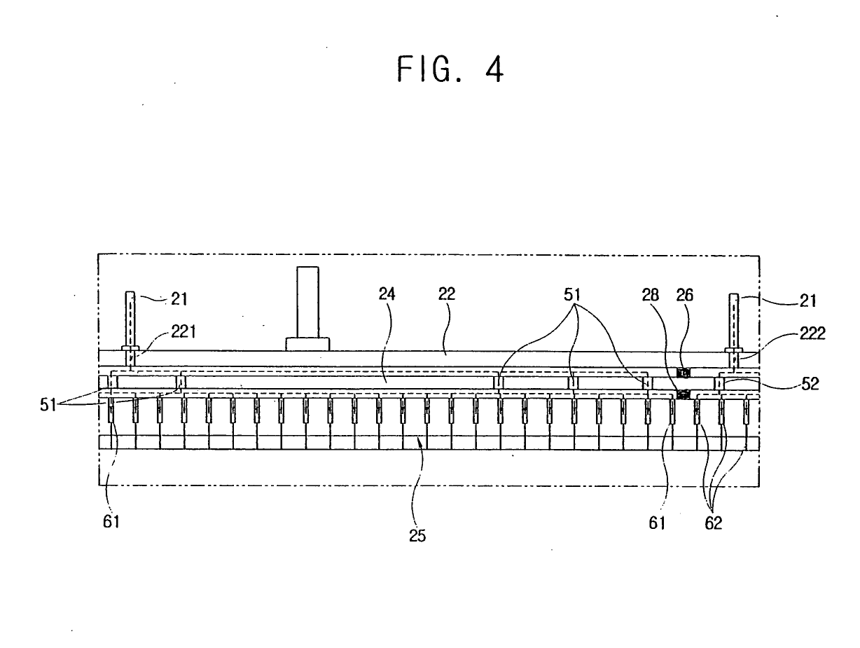

As shown in FIG. 3 and FIG. 4, in the gas supplier 22, the first gas supply hole 221 and the second gas supply hole 222 are disposed forming a gap therebetween. The first gas supply hole 221 is connected to a first central zone 31 (to be described later) passing through a plate corresponding to the first central zone 31, whereas the second gas supply hole 222 is connected to a first edge zone 32 (to be described later) passing through the plate corresponding to the first edge zone 32. The first gas supply hole 221 leads the reaction gas to flow into the first central zone 31 and the second gas supply hole 22 leads the reaction gas to flow into the first edge zone 32.

In the gas distributor 24, a loop-type upper partition wall 26 protrudes from a central zone of an upper surface and a loop-type bottom partition wall 28 protrudes from a central zone of a bottom surface.

Thus, the first gap 30 formed between the gas supplier 22 and the gas distributor 24 is divided into the first central zone 31 and the first edge zone 32 by the upper partition wall, and the second gap 40 formed between the gas distributor 24 and the showerhead 25 is divided into a second central zone 41 and a second edge zone 42 by the bottom partition wall 28.

In the first central zone 31, a plurality of first gas distribution holes 51 are connected to the second central zone 41 passing through a plate of the gas distributor 24, and a plurality of second gas distribution holes 52 are connected to the second edge zone 42 passing through the plate of the gas distributor 24 in the first edge zone 32.

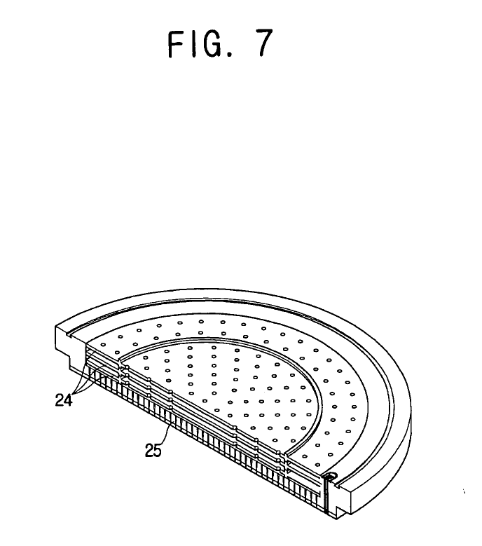

The gas distributor 24 may contain an aluminium alloy, and the showerhead 25 may contain silicon. In the above embodiment of the present invention, one gas distributor 24 is provided between the gas supplier 24 and the showerhead 25, but a plurality of gas distributors 24 are alternatively layered as shown in FIG. 7.

A description of an operation of the etching apparatus according to an aspect of the present invention follows.

The reaction gas passes through the first gas supplier 221 and the second gas supplier 222 of the gas supplier 22. The reaction gas is circulated in the first gap 30 formed between the gas supplier 22 and the gas distributor 24. The reaction gas passed through the first gas supply hole 221 flows into the first central zone 31 of the first gap 30, and the reaction gas passed through the second gas supply hole 222 flows to the first edge zone 32 of the first gap 30.

The reaction gas in the first gap 30 is divided between the first central zone 31 and the first edge zone 32. The reaction gas from the first central zone then flows into the second central zone 41 of the second gap 40 formed between the gas distributor 24 and the showerhead 25. The gas passes through the first gas supply hole 51 placed in the first central zone 31. The gas from the first edge zone 32 flows into the second edge zone 42 of the second gap 40 formed between the gas distributor 24 and the showerhead 25 and passes through the second gas supply hole 52 of the gas distributor 24 placed in the first edge zone 32.

The reaction gas that flowed into the second central zone 41 is injected into the chamber 1 through a plurality of first distribution holes 61 provided in the showerhead 25 and disposed in the second central zone 41. The reaction gas flowing into the second edge zone 42 is injected into the chamber 1 of the etching apparatus through a plurality of second distribution holes 62 of the showerhead 25 disposed in the second edge zone 42.

The reaction gas is supplied into the chamber 1 and converted into plasma by electrodes formed in the gas injector 2 and the support 3, and the semiconductor wafer 4 placed on the support 3 is etched. The reaction gas is injected outside of the chamber 1 through the gas outlet 5 provided in a bottom part of the chamber 1 when the etching is completed.

With the upper partition wall 26 and the bottom partition wall 28 structure according to an aspect of the present invention, the gas distributor 24 can separately inject reaction gas to a central zone inside the chamber 1 through the plurality of first distribution holes 61, and an edge zone inside the chamber 1 through the plurality of second distribution holes 62. Therefore, the amount of the reaction gas supplied into the central zone and the edge zone of the chamber 1 can be independently controlled.

If the amount of the reaction gas in the central zone of the chamber 1 is different from the amount of reaction gas in the edge zone of the chamber 1, the amounts of reaction gas in the central and the edge zones are independently changeable. The amount of the reaction gas in the zone initially having less gas is increased, and the amount of gas in the other zone initially having more gas is decreased. Therefore, aspects such as density and speed of the gas on the semiconductor wafer 4 and uniformity of density of plasma, deposition speed, etching speed, and the like in the etching process can be controlled.

The increasing or decreasing of the amount of reaction gas in the central zone, the edge zone of the chamber 1, or one zone independently from the other zone, according to an aspect of the present invention, is possible because the reaction gas is divided, into the first central zone 31 and the first edge zone 32, and into the second central zone 41 and the second edge zone 42 by the upper partition wall 26 and the bottom partition wall 28, without being mixed while the reaction gas is passing through the gas distributor 24.

The etching apparatus according to an aspect of the present invention also includes an MFC (Mass Flow Controller). The amount of reaction gas supplied into the first central zone 31 formed between the gas supplier 22 and the gas distributor 24 is increased or decreased independently from the first edge zone 32, and the amount of reaction gas supplied into the first edge zone 32 is increased or decreased independently from the first central zone 31. The MFC accurately controls the amount of various kinds of gas a user wants that are used for a semiconductor manufacturing.

In an MFC, a fluid is heated if a heating material is positioned in the path of the fluid flow. The temperature between an upper stream and a lower stream of the fluid for the heating material is initially different, but the heating material loses heat and cools down. A valve for the fluid is controlled by an electric signal generated after estimating a speed and amount of the fluid by detecting the above change of the temperature. According to an aspect of the invention, the MFC includes a sensor, a control valve, a bypass, a base block, and an electric circuit.

As described above, the MFC is used to control a valve. According to an aspect of the present invention, the etching apparatus further comprises a control valve automatically operated by a controller. Therefore, the amount of reaction gas supplied to the first central zone 31 and the first edge zone 32 respectively is controlled. The control valve is automatically controlled by the control part or controlled manually.

As described above, aspects of the present invention provide an etching apparatus independently controlling the amounts of reaction gas injected into a central zone and an edge zone of a chamber when the reaction gas is injected into the chamber, and thereby controlling uniformity of factors affecting etching such as density of plasma, deposition speed, etching speed, and the like in the etching process.

Although a few embodiments of the present invention have been shown and described, it will be appreciated by those skilled in the art that changes may be made in these embodiments without departing from the principles and spirit of the invention, the scope of which is defined in the appended claims and their equivalents.

1. An etching apparatus for a semiconductor wafer, comprising:
a vacuum chamber;
a support for the semiconductor wafer in the chamber; and
a gas injector,
wherein the gas injector comprises:
a first gas supplier,
a second gas supplier independently providing gas from the first gas supplier,
a gas distributor plate having an upper central zone and an upper edge zone and a lower central zone and a lower edge zone, and
a showerhead opposing the gas distributor,
wherein an amount of reaction gas supplied to the upper central zone and the upper edge zone of the gas distributor is independently controlled.

2. The etching apparatus for a semiconductor wafer according to claim 1, wherein the gas distributor plate has a loop-type upper partition wall protruding from the central zone of an upper side of the plate, and a loop-type bottom partition wall protruding from the central zone of a bottom side of the plate.

3. The etching apparatus according to claim 1, wherein a first gap is formed between the gas distributor and the gas suppliers, and a second gap is formed between the gas distributor plate and the showerhead.

4. The etching apparatus according to claim 3, wherein at least one of uniformity of density of plasma, deposition speed, and etching speed is controlled.

5. The etching apparatus according to claim 1, wherein a plurality of the gas distributor plates are provided between the gas suppliers and the showerhead.

6. The etching apparatus according to claim 2, wherein the upper partition wall divides a first gap into a first central zone and a first edge zone, and the bottom partition wall divides a second gap into a second central zone and a second edge zone.

7. The etching apparatus according to claim 6, wherein at least one of uniformity of density of plasma, deposition speed, and etching speed is controlled.

8. The etching apparatus according to claim 6, wherein either one of the gas suppliers connects to the first central zone, and the other one connects to the first edge zone.

9. The etching apparatus according to claim 8, wherein the first central zone has a plurality of first gas distribution holes connected with the second central zone and passing through a planar side of the gas distributor plate, and the first edge zone has a plurality of second gas distribution holes connected with the second edge zone and passing through the planar side of the gas distributor plate.

10. The etching apparatus according to claim 9, wherein the first gas distribution holes are alternately arranged with the second gas distribution holes.

11. The etching apparatus according to claim 6, further comprising an MFC (Mass Flow Controller) independently controlling amounts of reaction gases respectively supplied into the first central zone and the first edge zone.

12. The etching apparatus according to claim 8, further comprising an MFC (Mass Flow Controller) independently controlling amounts of reaction gas respectively supplied into the first central zone and the first edge zone.

13. The etching apparatus according to claim 9, further comprising an MFC (Mass Flow Controller) independently controlling amounts of reaction gas respectively supplied into the first central zone and the first edge zone.

14. The etching apparatus according to claim 6, further comprising a control valve independently supplying the reaction gas into the first central zone and the first edge zone.

15. The etching apparatus according to claim 14, wherein the control valve is controlled automatically.

16. The etching apparatus according to claim 8, further comprising a control valve independently supplying the reaction gas into the first central zone and the first edge zone.

17. The etching apparatus according to claim 16, wherein the control valve is controlled automatically.

18. The etching apparatus according to claim 9, further comprising a control valve independently supplying the reaction gas into the first central zone and the first edge zone.

19. The etching apparatus according to claim 18, wherein the control valve is controlled automatically.

20. The etching apparatus according to claim 9, wherein the gas distributor plate contains aluminuim alloy, and the showerhead contains silicon.

21. A method of controlling uniformity of factors contributing to uniform etching of a semiconductor wafer, comprising:
supplying a reaction gas from first and second gas suppliers;
flowing the supplied reaction gas from the first supplier into a first central zone in a first gap between the gas suppliers and a gas distributor;
flowing the supplied reaction gas from the second supplier into a first edge zone in the first gap;
flowing the gas from the first central zone into a second central zone of a second gap between the gas distributor and a showerhead;
flowing the gas from the first edge zone into a second edge zone of the second gap;
injecting the gas from the second central zone into the chamber; and
injecting the gas from the second edge zone into the chamber.

22. The method according to claim 21, further comprising:
applying RF power to the gas suppliers;
forming the gas distributor as an upper electrode and a support holding the wafer as a bottom electrode;
converting the reaction gas into plasma using the upper and bottom electrodes; and
ejecting a flue gas after etching.

23. The method according to claim 22, further comprising independently controlling a supply of reaction gas into the central zone and edge zone of the chamber.

24. The method according to claim 23, wherein independently controlling the supply of reaction gas comprises increasing an amount of reaction gas in a zone having less gas and decreasing an amount of reaction gas in a zone having more gas.

25. The method according to claim 24, wherein the independently controlling the supply of reaction gas comprises:
heating a fluid by heating material positioned in the path of the fluid flow,
detecting a change in temperature,
estimating a speed of the fluid and an amount of the fluid flowing by the detected change, and
controlling a valve with an electric signal based on the estimated speed and fluid amount.

26. The method according to claim 21, wherein the factor controlled contributing to the uniform etching is at least one of density of plasma, deposition speed, and etching speed.

27. A gas injector for an etching apparatus, comprising:
a first gas supplier;
a second gas supplier independently providing gas from the first gas supplier;
a gas distributor plate having an upper central zone and an upper edge zone and a lower central zone and a lower edge zone; and
a showerhead opposing the gas distributor,
wherein an amount of reaction gas supplied to the upper central zone and the upper edge zone of the gas distributor is independently controlled.

28. The gas injector according to claim 27, wherein the first or the second gas supplier connects to the upper central zone and the other connects to the upper edge zone.

29. The gas injector according to claim 28, wherein the upper central zone is connected with the lower central zone and the upper edge zone is connected with the lower edge zone.
